(19) United States
(12) Patent Application Publication
(10) Pub. No.: US 2024/0188435 A1
(43) Pub. Date: Jun. 6, 2024

(54) ORGANIC METAL HALIDE HYBRIDS, ELECTRICALLY DRIVEN LIGHT EMITTING DIODES, AND METHODS

(71) Applicant: Florida State University Research Foundation, Inc., Tallahassee, FL (US)

(72) Inventors: He Liu, Tallahassee, FL (US); Biwu Ma, Tallahassee, FL (US)

(21) Appl. No.: 18/520,933

(22) Filed: Nov. 28, 2023

Related U.S. Application Data
(60) Provisional application No. 63/385,106, filed on Nov. 28, 2022.

(51) Int. Cl. H10K 85/60; C07F 9/572; C09K 11/06

(52) U.S. Cl. CPC H10K 85/6572; C07F 9/5728; C09K 11/06; H10K 50/11

(57) ABSTRACT

Organic metal halide hybrids (OMHHs) that can be used as improved materials (e.g., emitter materials) for electrically driven LEDs are provided, as well as methods of fabricating the same. The OMHHs can be highly luminescent and conductive zero-dimensional (0D) OMHHs. Efficient LEDs can include one or more of the OMHHs described herein. For example, the OMHH can be (and the LEDs can be based on) solution processed TPPcarzSbBr₄ thin films and/or TPPcarzSbBr₄ single crystals.

### CROSS-REFERENCE TO RELATED APPLICATION

This application claims the benefit of U.S. Provisional Application Ser. No. 63/385,106, filed Nov. 28, 2022, the disclosure of which is hereby incorporated by reference in its entirety, including all figures, tables, and drawings.

### GOVERNMENT SUPPORT

This invention was made with government support under Contract Nos. 2204466 and 1912911, awarded by the National Science Foundation (NSF). The government has certain rights in this invention.

### BACKGROUND

Electrically driven light emitting diodes (LEDs) have a number of applications, ranging, for example, from full-color displays to solid-state lighting. Numerous types of light emitting materials and device configurations have been explored to date for use in electrically driven LEDs, including epitaxially grown inorganic semiconductors based LEDs, organic LEDs, and quantum dot LEDs.

Despite the rapid pace of development, electrically driven LEDs have not achieved their full potential in terms of performance, cost efficiency, and other metrics. Therefore, identifying new low-cost materials for high performance LEDs that can be easily processed is of great scientific and practical interest.

### BRIEF SUMMARY

Embodiments of the subject invention provide novel and advantageous organic metal halide hybrids (OMHHs) that can be used as improved materials (e.g., emitter materials) for electrically driven LEDs, as well as methods of fabricating the same. The OMHHs can be highly luminescent and conductive zero-dimensional (0D) OMHHs. Embodiments also provide efficient LEDs that include one or more of the OMHHs described herein. For example, the OMHH can be (and the LEDs can be based on) solution processed TPPcarzSbBr₄ thin films (PLQE of 86.1%). The LEDs can exhibit external quantum efficiencies (EQEs) of, for example at least 5.12%, with a peak luminance of, for example, at least 5957 candelas per square meter (cd/m²), which are the highest values achieved to date for electroluminescence devices based on 0D OMHHs.

In an embodiment, an OMHH can have the formula (Cat)ₐM^{+b}X_{y}, where Cat is a phosphonium cation comprising a phosphorus atom substituted with three aryl C₁-C₂₀ hydrocarbyl substituents and one heteroaryl C₁-C₂₀ hydrocarbyl substituent, where M is a metal, where b is the oxidation state of the metal, and where X is a halogen. For example, a+b can equal y. The heteroaryl C₁-C₂₀ hydrocarbyl substituent can comprise a carbazole moiety, such as a phenyl-carbazole moiety. The three aryl C₁-C₂₀ hydrocarbyl substituents can be phenyl. The phosphonium cation can be, for example, triphenyl(9-phenyl-9H-carbazol-3-yl) phosphonium with the structure shown in FIG. 18. M can be a metal other than lead (Pb). For example, M can be antimony (Sb). X can be, for example, bromine (Br). The OMHH can have a 0D crystal structure. The OMHH can have a crystal structure comprising light emitting antimony bromide dimer anions (Sb₂Br₈²⁻) surrounded and isolated by the phosphonium cation. The OMHH can be in the form of discrete crystals, and the discrete crystals can have a photoluminescent quantum efficiency (PLQE) of at least 90%. The OMHH can be in the form of a thin film, and the thin film can have a PLQE of at least 85%. The OMHH can have a structure of, for example, the following formula: (triphenyl(9-phenyl-9H-carbazol-3-yl) phosphonium)+SbBr₄.

In another embodiment, an electrically driven LED can comprise: a first electrode; a light emitting layer comprising an OMHH as disclosed herein; and a counter electrode. The light emitting layer can be disposed between the first electrode and the counter electrode. The device can further comprise at least one of: a hole transporting layer disposed between the first electrode and the light emitting layer; and an electron transporting layer disposed between the counter electrode and the light emitting layer. The device can be a hole-only device. The device can be an electron-only device.

### BRIEF DESCRIPTION OF DRAWINGS

FIG. 1(a) shows a schematic illustration of an approach to addressing the low conductivity and poor energy alignment of existing zero-dimensional (0D) organic metal halide hybrids (OMHHs) for electrically driven light emitting diodes (LEDs), according to an embodiment of the subject invention. Existing 0D OMHHs include metal halide polyhedral (represented by the diamond shapes near the middle of the image) embedded in an organic host matrix (represented by the shaded rectangle on which the diamond shapes are shown) based on triphenyl(9-phenyl-9H-carbazol-3-yl) phosphonium (TPP+). The bottom portion of the figure shows an energy diagram of an LED with a hole transport layer (HTL), an electron transport layer (ETL), and an emitting layer based on 0D OMMHs, in order to show how the change of emitting layer could lead to better charge injection, transport, and recombination.

FIG. 1(b) shows a schematic illustration of an approach to addressing the low conductivity and poor energy alignment of 0D OMHHs for electrically driven LEDs, according to an embodiment of the subject invention. New 0D OMHHs include metal halide polyhedral (represented by the bowtie shapes near the middle of the image) embedded in an organic host matrix (represented by the shaded rectangle on which the bowtie shapes are shown) based on triphenyl(9-phenyl-9H-carbazol-3-yl) phosphonium (TPPcarz+). The bottom portion of the figure shows an energy diagram of an LED with an HTL, an ETL, and an emitting layer based on 0D OMMHs, in order to show how the change of emitting layer could lead to better charge injection, transport, and recombination.

FIG. 2(a) shows a synthetic scheme for the preparation of triphenyl(9-phenyl-9H-carbazol-3-yl)phosphonium bromide (TPPcarzBr).

FIG. 2(b) shows antisolvent diffusion growth of triphenyl(9-phenyl-9H-carbazol-3-yl)phosphonium antimony bromide (TPPcarzSbBr₄) single crystals.

FIG. 2(c) shows an image of TPPcarzSbBr₄ single crystals under ambient light.

FIG. 2(d) shows an image of TPPcarzSbBr₄ single crystals under ultraviolet (UV) excitation (at a wavelength of 365 nanometers (nm)).

FIG. 2(e) shows the crystal structure of TPPcarzSbBr4, in which edges shared antimony bromide dimers Sb₂Br₈²⁻ are surrounded and isolated by TPPcarz+.

FIG. 3(a) shows an image of a solution processed TPPcarzSbBr₄ thin film under ambient light.

FIG. 3(b) shows an image of a solution processed TPPcarzSbBr₄ thin film under UV (365 nm) light.

FIG. 3(c) shows a plot of intensity (in arbitrary units (a.u.)) versus 2θ (in degrees), showing powder X-ray diffraction (PXRD) patterns of TPPcarzSbBr₄ in solid (the curve with the higher intensity values) and thin film (the curve with the lower intensity values) states.

FIG. 3(d) shows, from left to right, a scanning electron microscopy (SEM) image of a solution processed TPPcarzSbBr₄ thin film, and corresponding elemental mapping of antimony (Sb), bromine (Br), carbon (C), nitrogen (N), and phosphorous (P).

FIG. 3(e) shows a plot of normalized intensity versus wavelength (in nm), showing photoluminescence (PL) spectra and photoluminescence excitation (PLE) spectra of TPPcarzSbBr₄ single crystals and solution processed TPPcarzSbBr₄ thin films. The solid curve with the peak around 450 nm is for PLE of solution processed TPPcarzSbBr₄ thin film; the solid curve with the peak around 650 nm is for PL of solution processed TPPcarzSbBr₄ thin film; the dashed curve with the peak around 450 nm is for PLE of TPPcarzSbBr₄ single crystals; and the dashed curve with the peak around 650 nm is for PL of solution processed TPPcarzSbBr₄ single crystals.

FIG. 3(f) shows a plot of normalized intensity versus time (in microseconds (μs)), showing PL delay curves TPPcarzSbBr₄ single crystals (the square data points) and solution processed TPPcarzSbBr₄ thin films (the triangular data points).

FIG. 4(a) shows an SEM image of a solution processed TPPcarzSbBr₄ thin film. The scale bar is 1 micrometer (μm).

FIG. 4(b) shows an atomic force microscope (AFM) image of a solution processed TPPcarzSbBr₄ thin film. The scale bar is 400 nm.

FIG. 4(c) shows Nyquist plots of TPPcarzSbBr₄ based devices (inset shows Nyquist plots of TPP₂SbBr₅ based devices).

FIG. 4(d) shows a plot of current density (in milliamps per square centimeters (mA/cm²)) versus voltage (in Volts (V)) for electron-only and hole-only devices based on solution processed TPPcarzSbBr₄ and TPP₂SbBr₅ thin films. The curve with the square data points and the highest current density value at a voltage of 5V is for hole-only device of TPPcarzSbBr₄ thin films; the curve with the circular data points and the second-highest current density value at a voltage of 5V is for electron-only device of TPPcarzSbBr₄ thin films; the curve with the upside-down triangular data points and the third-highest current density value at a voltage of 5V is for electron-only device of TPP₂SbBr₅ thin films; and the curve with the triangular data points and the fourth-highest current density value at a voltage of 5V is for hole-only device of TPP₂SbBr₅ thin films.

FIG. 5(a) shows a device architecture of an electrically driven LED including a solution processed 0D OMHH emitting layer, according to an embodiment of the subject invention. Though certain materials and thicknesses are listed in FIG. 5(a), these are for exemplary purposes only and should not be construed as limiting.

FIG. 5(b) shows a plot of current density (in mA/cm²; left vertical axis) and luminance (in candelas per square meter (cd/m²); right vertical axis) versus voltage (in V). The curve with the square data points is for luminance; and the curve with the circular data points is for current density.

FIG. 5(c) shows a plot of external quantum efficiency (EQE; in percentage (%); left vertical axis) and current efficiency (in candelas per Amp (cd/A); right vertical axis) versus current density (in mA/cm²). The curve with the square data points is for current efficiency; and the curve with the circular data points is for EQE.

FIG. 5(d) shows a plot of electroluminescent (EL) intensity (in a.u.) versus wavelength (nm), showing EL spectra of LEDs based on TPPcarzSbBr4 at different operational voltages (the inset shows an image of a device at 5 V). The curve with the highest peak is for 8 V; the curve with the second-highest peak is for 7 V; the curve with the third-highest peak is for 6 V; and the curve with the lowest peak is for 5 V.

FIG. 6 shows ¹H nuclear magnetic resonance (NMR) spectrum of TPPcarzBr in deuterated chloroform (CDCl₃).

FIG. 7(a) shows a plot of normalized absorption (Abs) versus wavelength (nm) for TPPBr (the dashed curve) and TPPcarzBr (the solid curve).

FIG. 7(b) shows a plot of current (in microamps (μA) versus potential with reference to silver (Ag) (E (V vs. Ag)), showing cyclic voltammogram curves obtained in dichloromethane solution with 0.1 molar (M) tetrabutylammonium hexafluorophosphate. The cyclic curve with the E values over 2.0 is for TPPcarzBr, and the other cyclic curve is for ferrocene.

FIG. 8 shows a table of results related to the plots in FIGS. 7(a) and 7(b).

FIG. 9(a) shows a plot of weight (in %) versus temperature (in ° C.), showing thermogravimetric analysis of TPPcarzSbBr₄.

FIG. 9(b) shows a plot of intensity (in a.u.) versus 2θ (in degrees), showing PXRD patterns of TPPcarzSbBr₄ and the corresponding simulated peaks from the single crystal structure. The curve with the higher intensity values is for expected, and the curve with the lower intensity values is for calculated.

FIG. 10(a) shows a plot of normalized Abs intensity versus wavelength (in nm), showing the absorption spectra of TPPcarzSbBr4 single crystals (solid curve) and solution processed thin films (dashed curve).

FIG. 10(b) shows a plot of PL intensity (in a.u.) versus wavelength (in nm), showing power dependent PL spectra of a solution processed TPPcarzSbBr₄ thin film. The inset shows the linear dependence of PL intensity on excitation power.

FIG. 11(a) shows a plot of intensity (in a.u.) versus wavelength (in nm), showing the photoluminescent quantum efficiency (PLQE) of TTPcarzSbBr₄ single crystals. The curve with the lowest intensity value at wavelength of 700 nm is for reference, and the curve with the highest intensity value at wavelength of 700 nm is for TTPcarzSbBr₄ single crystals.

FIG. 11(b) shows a plot of intensity (in a.u.) versus wavelength (in nm), showing the PLQE of TTPcarzSbBr₄ thin films. The curve with the lowest intensity value at wavelength of 700 nm is for reference, and the curve with the highest intensity value at wavelength of 700 nm is for TTPcarzSbBr₄ thin films.

FIG. 12(a) shows a plot of normalized PL intensity (in a.u.) versus time (in months), showing the atmosphere stability of solution processed TPPcarzSbBr₄ thin films.

FIG. 12(b) shows a plot of normalized PL intensity (in a.u.) versus time (in months), showing the thermal stability of solution processed TPPcarzSbBr₄ thin films on the top of a 150° C. hot plate.

FIG. 13(a) shows a plot of current density (in mA/cm²) versus voltage (in V) for hole-only devices based on solution processed TPPcarzSbBr₄ thin films. The curve was fit using the space charge limit current (SCLC) method to obtain the hole mobility.

FIG. 13(b) shows a plot of current density (in mA/cm²) versus voltage (in V) for electron-only devices based on solution processed TPPcarzSbBr₄ thin films. The curve was fit using the SCLC method to obtain the electron mobility.

FIG. 14(a) shows a plot of number of devices versus EQE (in %), showing an EQE histogram of 30 TPPcarzSbBr₄ based LEDs.

FIG. 14(b) shows a plot of normalize luminance (in cd/m²) versus time (in minutes (min)), showing a half-lifetime (T₅₀) of a TPPcarzSbBr₄ based device measured at an initial luminance of about 100 cd/m².

FIG. 15 shows a table of single crystal data of TPPcarzSbBr₄.

FIG. 16 shows a table of selected bond distance and angles of TPPcarzSbBr₄.

FIG. 17 shows a table of carrier mobilities of 0D OMHHs films. The “*” in the reference column refers to Li et al. (Highly Efficient Light-Emitting Diodes Based on an Organic Antimony(III) Halide Hybrid. Angew Chem Int Ed Engl, 61 (6), e202113450, 2022; which is hereby incorporated by reference herein in its entirety). “This work” in the reference column refers to embodiments of the subject invention and/or examples presented in this application.

FIG. 18 shows a structure for triphenyl(9-phenyl-9H-carbazol-3-yl) phosphonium cation.

### DETAILED DESCRIPTION

Embodiments of the subject invention provide novel and advantageous organic metal halide hybrids (OMHHs) that can be used as improved materials (e.g., emitter materials) for electrically driven LEDs, as well as methods of fabricating the same. The OMHHs can be highly luminescent and conductive zero-dimensional (0D) OMHHs. Embodiments also provide efficient LEDs that include one or more of the OMHHs described herein. For example, the OMHH can be (and the LEDs can be based on) solution processed TPPcarzSbBr₄ thin films (PLQE of 86.1%) and/or TPPcarzSbBr₄ single crystals (PLQE of 93.8%). The LEDs can exhibit external quantum efficiencies (EQEs) of, for example at least 5% (e.g., 5.12% or about 5.12%), with a peak luminance of, for example, at least 5000 candelas per square meter (cd/m²) (e.g., 5957 cd/m² or about 5957 cd/m²), which are the highest values achieved to date for electroluminescence devices based on 0D OMHHs.

In the related art, metal halide perovskites and perovskite-related materials have emerged as light emitting materials with remarkable and highly tunable optical properties. Efficient near-infrared (NIR), red, green, and blue perovskite LEDs have been demonstrated with external quantum efficiencies (EQEs) of up to 22.2%, 24.4%, 28.1%, and 13.8%, respectively. While perovskite LEDs have great potential, lead-containing devices represent a major environmental and health concern that could limit their wide commercialization. Moreover, most halide perovskites and perovskite-related structures are metastable under normal atmospheric conditions, which is another obstacle to achieve for devices with long lifetimes.

Zero-dimensional (0D) organic metal halide hybrids (OMHHs) are a new class of light emitting materials with exceptional color tunability. While near-unity photoluminescence quantum efficiencies (PLQEs) have been obtained for a large number of 0D OMHHs, it remains challenging to employ them successfully as emitters for electrically driven LEDs, likely due to the low conductivity of wide band gap organic cations.

In searching for efficient lead-free perovskite-related light emitting materials with high stability, progress has been made with 0D OMHHs that include light emitting metal halide polyhedra fully isolated and surrounded by bulky organic cations. Due to the complete site isolation, 0D OMHHs may possess a desirable “host-dopant” structure, with light emitting metal halide species periodically embedded in a large bandgap organic host matrix. While high PLQEs of up to near-unity have been achieved in numerous 0D OMHHs, their application in electrically driven LEDs has not been widely considered. The poor conductivity and wide band gap of organic cations are some of the factors responsible for the inferior charge transport and energy level alignment in these low performance LEDs based on 0D OMHHs.

There remains a need for improved materials for electrically driven LEDs, such as OMHHs. There also remains a need for an effective molecular engineering-based approach for the preparation of highly luminescent and conductive 0D OMHHs for use as emitter materials in electrically driven LEDs. Embodiments of the subject invention address one or more of these needs.

Embodiments provide molecular engineering approaches for the preparation of highly luminescent and conductive 0D OMHHs for use as emitter materials in electrically driven LEDs. In some embodiments, room temperature co-crystallization of a semiconducting organic halide (e.g., TPPcarzBr) and a metal halide (e.g., SbBr₃) results in the 0D OMHH (e.g., 0D organic antimony halide hybrid—TPPcarzSbBr₄), which may be in the form of single crystals or a thin film. The 0D OMHH (e.g., TPPcarzSbBr₄) can exhibit red emission peaked at 653 nm with PLQEs of at least 90% (e.g., 93.8% or about 93.8%).

Embodiments also provide electrically driven LEDs, including high performance electrically driven LEDs based on solution processed thin films of 0D OMHHs (e.g., TPPcarzSbBr₄ thin films, PLQE of at least 86.1%), which exhibit EQEs of at least 5% (e.g., 5.12% or about 5.12%) with a peak luminance of at least 5000 cd/m² (e.g., 5957 cd/m² or about 5957 cd/m²), which are the highest such values achieved to date for electroluminescence devices based on 0D OMHHs.

In some embodiments, the OMHHs have a structure (e.g., a unit cell) according to the following formula:

(Cat)ₐM^{+b}X_{y} formula (I),

where Cat is a phosphonium cation comprising a phosphorus atom substituted with three aryl substituents, such as three aryl C1-C20 hydrocarbyl substituents, and one heteroaryl substituent, such as one heteroaryl C1-C20 hydrocarbyl substituent; where M is a metal; where b is the oxidation state of the metal; and where X is a halogen. In some embodiments, a+b=y. As used herein, the phrase “heteroaryl” refers to a hydrocarbyl that is aromatic and includes at least one heteroatom, such as a nitrogen.

In some embodiments, the heteroaryl C1-C20 hydrocarbyl substituent comprises a carbazole moiety, such as a phenyl-carbazole moiety. In some embodiments, the aryl C1-C20 hydrocarbyl substituents are phenyl. In some embodiments, the phosphonium cation is triphenyl(9-phenyl-9H-carbazol-3-yl) phosphonium (TPPcarz+), which has the structure shown in FIG. 18.

The metal (i.e., “M”) can be any metal capable of forming an OMHH material, as described herein. For example, M can be antimony (Sb). In many embodiments, M is not lead (Pb). X can be, for example, fluorine (F), chlorine (Cl), bromine (Br), or iodine (I). In some embodiments, X is Br.

In some embodiments, the OMHH has a 0D crystal structure. In some embodiments, the OMHH has a crystal structure comprising light emitting antimony bromide dimer anions (Sb₂Br₈²⁻) surrounded and isolated by the phosphonium cations, such as triphenyl(9-phenyl-9H-carbazol-3-yl) phosphonium cations. In some embodiments, the organic metal halide hybrid has a structure of the following formula:

(triphenyl(9-phenyl-9H-carbazol-3-yl) phosphonium)+SbBr₄.

The organic metal halide hybrids described herein may be in any physical form. In some embodiments, the OMHHs are in the form of discrete crystals (i.e., “single crystals”). The discrete crystals can have a PLQE of at least 90%, or at least 93%. In some embodiments, the OMHHs are in the form of a thin film. The thin film can have a PLQE of at least 85%, or at least 88%.

Embodiments of the subject invention provide electronic devices, such as electrically driven LEDs. In some embodiments, the electrically driven LEDs can include: an electrode; a layer comprising an OMHH as described herein; and a counter electrode. The layer comprising the OMHH may be disposed between the electrode and the counter electrode. The layer comprising the OMHH may be a light emitting layer. The layer comprising the OMHH can optionally be in direct physical contact with the electrode and/or the counter electrode.

In some embodiments, the electronic device can also include a hole transporting layer and/or an electron transporting layer. The hole transporting layer (if present) can be disposed between the electrode and the layer comprising the OMHH, and the electron transporting layer (if present) can be disposed between the counter electrode and the layer comprising the OMHH. The device may be a hole-only device, or an electron-only device. The hole transporting layer (if present) can be in direct physical contact with the electrode and/or the layer comprising the OMHH. The electron transporting layer (if present) can be in direct physical contact with the counter electrode and/or the layer comprising the OMHH.

In an embodiment, a method of fabricating an OMHH can include performing the method described in Example 1.

The phrases “C1-C20 hydrocarbyl,” and the like, as used herein, generally refer to aliphatic, aryl, or arylalkyl groups containing 1 to 20 carbon atoms. Examples of aliphatic groups, in each instance, include, but are not limited to, an alkyl group, a cycloalkyl group, an alkenyl group, a cycloalkenyl group, an alkynyl group, an alkadienyl group, a cyclic group, and the like, and includes all substituted, unsubstituted, branched, and linear analogs or derivatives thereof, in each instance having 1 to about 20 carbon atoms. Examples of alkyl groups include, but are not limited to, methyl, ethyl, propyl, isopropyl, n-butyl, t-butyl, isobutyl, pentyl, hexyl, isohexyl, heptyl, 4,4-dimethylpentyl, octyl, 2,2,4-trimethylpentyl, nonyl, decyl, undecyl and dodecyl. Cycloalkyl moieties may be monocyclic or multicyclic, and examples include cyclopropyl, cyclobutyl, cyclopentyl, cyclohexyl, and adamantyl. Additional examples of alkyl moieties have linear, branched and/or cyclic portions (e.g., 1-ethyl-4-methyl-cyclohexyl). Representative alkenyl moieties include vinyl, allyl, 1-butenyl, 2-butenyl, isobutylenyl, 1- pentenyl, 2-pentenyl, 3-methyl-1-butenyl. 2-methyl-2-butenyl, 2,3-dimethyl-2-butenyl, 1- hexenyl, 2-hexenyl, 3-hexenyl, 1-heptenyl, 2-heptenyl, 3-heptenyl, 1-octenyl, 2-octenyl, 3- octenyl, 1-nonenyl, 2-nonenyl, 3-nonenyl, 1-decenyl, 2-decenyl and 3-decenyl. Representative alkynyl moieties include acetylenyl, propynyl, 1-butynyl, 2-butynyl, 1-pentynyl, 2-pentynyl, 3- methyl-1-butynyl, 4-pentynyl, 1-hexynyl, 2-hexynyl, 5-hexynyl, 1-heptynyl. 2-heptynyl, 6- heptynyl, 1-octynyl, 2-octynyl, 7-octynyl, 1-nonynyl, 2-nonynyl, 8-nonynyl, 1-decynyl, 2- decynyl and 9-decynyl. Examples of aryl or arylalkyl moieties include, but are not limited to, anthracenyl, azulenyl, biphenyl, fluorenyl, indan, indenyl, naphthyl, phenanthrenyl, phenyl, 1,2,3,4-tetrahydro-naphthalene, tolyl, xylyl, mesityl, benzyl, and the like, including any heteroatom substituted derivative thereof.

Unless otherwise indicated, the term “substituted,” when used to describe a chemical structure or moiety, refers to a derivative of that structure or moiety wherein (i) a multi-valent non-carbon atom (e.g., oxygen, nitrogen, sulfur, phosphorus, etc.) is bonded to one or more carbon atoms of the chemical structure or moiety (e.g., a “substituted” C4 hydrocarbyl may include, but is not limited to, diethyl ether moiety, a methyl propionate moiety, an N,N-dimethylacetamide moiety, a butoxy moiety, etc., and a “substituted” aryl C12 hydrocarbyl may include, but is not limited to, an oxydibenzene moiety, a benzophenone moiety, etc.) or (ii) one or more of its hydrogen atoms (e.g., chlorobenzene may be characterized generally as an aryl C6 hydrocarbyl “substituted” with a chlorine atom) is substituted with a chemical moiety or functional group such as alcohol, alkoxy, alkanoyloxy, alkoxycarbonyl, alkenyl, alkyl (e.g., methyl, ethyl, propyl, t-butyl), alkynyl, alkylcarbonyloxy (—OC(O)alkyl), amide (—C(O)NH-alkyl- or -alkylNHC(O)alkyl), tertiary amine (such as alkylamino, arylamino, arylalkylamino), aryl, aryloxy, azo, carbamoyl (—NHC(O)O-alkyl- or —OC(O)NH-alkyl), carbamyl (e.g., CONH₂, as well as CONH-alkyl, CONH-aryl, and CONH-arylalkyl), carboxyl, carboxylic acid, cyano, ester, ether (e.g., methoxy, ethoxy), halo, haloalkyl (e.g., —CCl₃, —CF₃, —C(CF₃)₃), heteroalkyl, isocyanate, isothiocyanate, nitrile, nitro, oxo, phosphodiester, sulfide, sulfonamido (e.g., SO₂NH₂), sulfone, sulfonyl (including alkylsulfonyl, arylsulfonyl and arylalkylsulfonyl), sulfoxide, thiol (e.g., sulfhydryl, thioether) or urea (—NHCONH-alkyl-).

While certain aspects of conventional technologies have been discussed to facilitate disclosure of various embodiments, applicants in no way disclaim these technical aspects, and it is contemplated that the present disclosure may encompass one or more of the conventional technical aspects discussed herein.

The present disclosure may address one or more of the problems and deficiencies of known methods and processes. However, it is contemplated that various embodiments may prove useful in addressing other problems and deficiencies in a number of technical areas. Therefore, the present disclosure should not necessarily be construed as limited to addressing any of the particular problems or deficiencies discussed herein.

The terms “a,” “an,” and “the” are intended to include plural alternatives, e.g., at least one. For instance, the disclosure of “an antisolvent”, “a triaryl amine”, and the like, is meant to encompass one, or mixtures or combinations of more than one antisolvent, triaryl amine, and the like, unless otherwise specified.

When ranges are used herein, combinations and subcombinations of ranges (e.g., any subrange within the disclosed range) and specific embodiments therein are intended to be explicitly included. When the term “about” is used herein, in conjunction with a numerical value, it is understood that the value can be in a range of 95% of the value to 105% of the value, i.e. the value can be +/−5% of the stated value. For example, “about 1 kg” means from 0.95 kg to 1.05 kg.

A greater understanding of the embodiments of the subject invention and of their many advantages may be had from the following examples, given by way of illustration. The following examples are illustrative of some of the methods, applications, embodiments, and variants of the present invention. They are, of course, not to be considered as limiting the invention. Numerous changes and modifications can be made with respect to embodiments of the invention.

### Materials and Methods

The examples describe a molecular engineering approach to addressing the issues of low conductivity and poor energy alignment in electrically driven LEDs based on 0D OMHHs.

By introducing a simple organic charge transporting unit (phenylcarbazole) to a triphenyl(9-phenyl-9H-carbazol-3-yl) phosphonium (TPP+) cation, a semiconducting organic cation—triphenyl(9-phenyl-9H-carbazol-3-yl) phosphonium (TPPcarz+) was produced (see also, Xu et al., Ligand-Mediated Release of Halides for Color Tuning of Perovskite Nanocrystals with Enhanced Stability, The Journal of Physical Chemistry Letters, 10 (19), 5836-5840, 2019; which is hereby incorporated by reference herein in its entirety).

A 0D OMHH TPPcarzSbBr₄ was then synthesized, in which light emitting antimony bromide dimer anions (Sb₂Br₈²⁻) were surrounded and isolated by TPPcarz+. Both single crystals and solution processed thin films of TPPcarzSbBr₄ were found to exhibit red emission with high PLQEs of 93.8% and 86.1%, respectively.

Electrically driven LEDs with solution processed TPPcarzSbBr₄ emitting layer exhibited an EQE of 5.12%, a peak luminance of 5957 cd/m², and a current efficiency of 14.2 candelas per Amp (cd/A), the best values reported to date for 0D-OMHH-based electroluminescence devices.

Chemicals: poly(3,4-ethylenedioxythiophene) polystyrene sulfonate (PEDOT:PSS) (CH8000) was purchased from Heraeus. Antimony(III) bromide, Zinc acetate dihydrate, Triphenylphosphine (TPP, Aldrich, 99%), 3-bromo-9- phenylcarbazole, zinc acetate dihydrate, poly(N-vinylcarbazole) (PVK), lithium fluoride (LiF), dichloromethane (DCM, 99.5%) and diethyl ether (Et₂O, anhydrous), dimethylformamide (DMF, anhydrous), and hydrobromic acid (48%) were purchased from Sigma-Aldrich. Chlorobenzene (anhydrous, 99.8%) and ethylene glycol was purchased from VWR. All reagents and solvents were used without further purification unless otherwise stated.

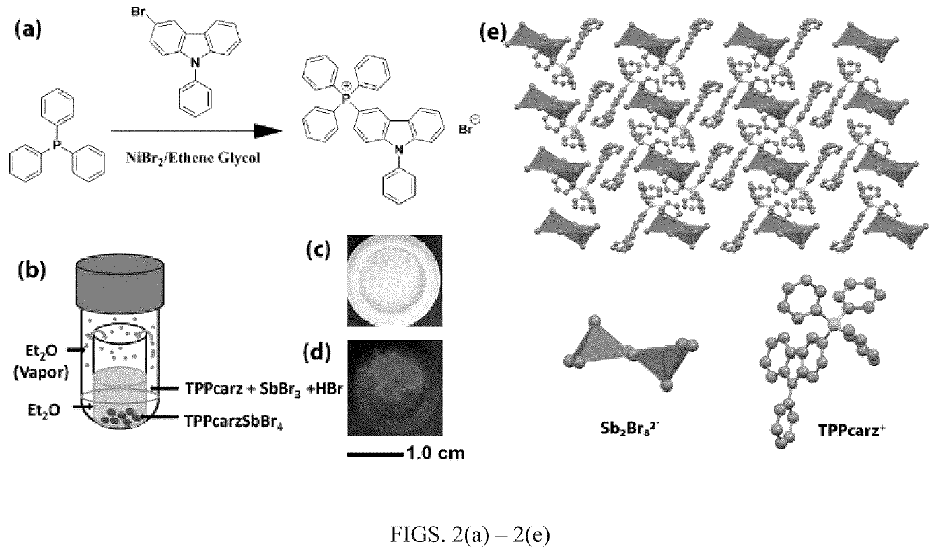

Synthesis of triphenyl(9-phenyl-9H-carbazol-3-yl)phosphonium bromide(TPPcarzBr): The TPPcarzBr was synthesized according to the scheme shown in FIG. 2(a) (see also Xu et al., supra.). Triphenylphosphine (524 milligrams (mg), 2 millimolar (mmol)), 3-bromide-9-phenylcarbazole (644 mg, 2 mmol), and NiBr₂ (50 mg, 0.2 mmol) were added in 5 milliliters (ml) of ethylene glycol solution with stirring for 5 hours (h) at 150° C. Then, the deep green solution dissolved in water and was extracted with CH₂Cl₂. Diethyl ether was used to wash the white powder product out. The yield was 95% and the ¹H NMR (500 megahertz (MHz), CDCl₃, δ) results were: 8.28-8.22 (d, 1H), 8.10-8.05 (d, 1H), 7.98-7.89 (m, 3H), 7.85-7.78 (m, 6H), 7.74-7.63 (m, 9H), 7.59-7.48 (m, 5H), 7.45-7.41 (d, 1H), 7.39-7.35(t, 1H).

Growth of TPPcarzSbBr₄ single crystals via antisolvent vapor diffusion: 0.2 mmol SbBr₃ and 0.4 mmol TPPcarzBr were mixed at a 1:2 molar ratio and dissolved in 1 mL ethanol and 0.1 mL HBr to form a clear precursor solution. Two ml of Et₂O were diffused into this precursor solution at room temperature overnight.

Preparation of ZnO nanocrystals: ZnO nanocrystals were synthesized (see also Shi et al., Strategy of Solution-Processed All-Inorganic Heterostructure for Humidity/Temperature-Stable Perovskite Quantum Dot Light-Emitting Diodes, ACS Nano 12 (2), 1462-1472, 2018; which is hereby incorporated by reference herein in its entirety). Zinc acetate dihydrate (2.29 grams (g)) was dissolved in 10 mL of methanol with vigorous stirring. KOH (1.48 g) was dissolved in 5 mL of methanol and then added slowly into the zinc acetate solution and continuously stirred for an additional 120 minutes (60° C.). The above solution was centrifuged at 4200 revolutions per minute (rpm) for 3 minutes to collect the white precipitate. The white precipitate was dispersed in chlorobenzene to obtain a ZnO nanocrystals solution.

Device fabrication and characterization: The LEDs were fabricated with the configuration of indium tin oxide (ITO)/PEDOT:PSS (40 nm thickness)/PVK (35 nm)/TPPcarzSbBr₄ (40 nm)/ZnO (40 nm)/LiF (2 nm)/aluminum (Al) (100 nm). ITO substrates were cleaned by sonication in deionized water, acetone, and isopropanol, followed by nitrogen purge and ultraviolet-ozone treatment for 20 minutes. PEDOT:PSS was spin-coated at 4500 rpm for 60 seconds and baked at 150° C. for 20 minutes. PVK (in chlorobenzene, 8 milligrams per milliliter (mg/mL)) was deposited on top of PEDOT:PSS at 2000 rpm for 45 seconds, followed by drying at 150° C. for 20 minutes. The light-emitting layer was deposited layer by layer by spin coating at 2500 rpm for 45 seconds using a precursor solution (0.2 mmol of SbBr₃ and 0.4 mmol of TPPcarzBr in a 1:2 molar ratio in 1 mL DMF). Subsequently, the ZnO nanoparticles solution (chlorobenzene, 3%) were then spin-coated at 2500 rpm for 45 seconds, followed by an annealing treatment at 100° C. for 10 minutes. Finally, 2 nm of LiF and 100 nm of Al were thermally deposited under high vacuum of about 1×10⁻⁶ Torr. Devices for capacitance study were fabricated with the configuration of ITO/PEDOT:PSS (40 nm)/PVK (35 nm)/TPPcarzSbBr₄ (40 nm)/calcium (Ca) (20 nm)/Al (100 nm). Hole-only and electron-only devices were fabricated using the device structures ITO/PEDOT:PSS (40 nm)/TPPcarzSbBr₄ (40 nm)/molybdenum oxide (MoOx) (10 nm)/Al (100 nm) and ITO/tin oxide (SnO₂) (30 nm)/TPPcarzSbBr₄ (40 nm)/LiF (2 nm)/Al (100 nm), respectively. The electroluminescence (EL) spectra were recorded by a USB4000 spectrometer. The current density-voltage-brightness (I-V-B) curves of the devices were measured with a Keithley 2400 source meter coupled to a silicon (Si) photodiode. All tests of the devices were conducted at room temperature under ambient conditions.

Characterization: Single crystal X-ray crystallography data was collected using Rigaku XtaLAB Synergy-S diffractometer equipped with a HyPix-6000HE Hybrid Photon Counting (HPC) detector and copper (Cu) microfocus sealed X-ray sources at 295 Kelvin (K). The powder X-ray diffraction patterns were obtained using a Rigaku Smartlab powder diffractometer equipped with a Cu Kα X-ray source. ¹H NMR B500 was equipped with a high resolution 5 millimeter (mm) TXI (H-C/N-D) Zg probe. TGA was obtained on a TA instruments TGA 550 system. The sample was heated from room temperature to 700° C. at a rate of 5° C./minute. Absorption spectra were conducted using an Agilent Technologies Cary 5000 UV-Vis-NIR spectrophotometer. PL measurements were done at an excitation wavelength of 365 nm via an Edinburgh FS5 steady state spectrometer with a 150 W xenon lamp. The corresponding time-resolved PL spectra were recorded by the same instrument which equipped a 365 nm laser (Edinburgh Instruments). The carrier lifetimes were fitted with a single exponential function, as follows: y=A1×exp(−x/τ1)+y0. PLQE measurements were carried out at an excitation wavelength of 365 nm using a quantaurus absolute QY Spectrometer from Hamamatsu. The PLQE values were calculated by the equation: ηQE=Iₛ/(E_{R}−E_{S}), where Iₛ represents the emission spectra of samples, E_{R} represents the spectra of the excitation light for the reference (blank substrate), and Eₛ represents the excitation spectra for exciting the sample.

Cyclic voltammetry data were collected using Epsilon E2 electrochemical analyzer in an electrolyte (0.1 moles per liter 9 mol/L) solution of tetrabutylammonium hexylfluorophosphate in dichloromethane) initially de-aerated by argon (Ar). Measurements were conducted in a three-electrode electrochemical cell: platinum (Pt) counter electrode, silver (Ag) pseudo reference electrode, and glassy carbon electrodes working and with a 100 millivolt per second (mV/s) of potential scan rate. The potentials were determined versus Fc+/Fc (ferrocene) reference potential. The AFM picture was captured with a Bruker Icon scanning probe microscope in tapping-mode. The SEM pictures were captured by Nova NanoSEM 400 (FEI Company) at 3.0 kilovolts (kV) scanning voltage. The ultrafast transient absorption data were collected using a femtosecond (fs) pump-probe system. The output from a Ti:sapphire laser was split into two beams: one was used to generate the pump; another beam was sent to a spectrometer to generate the probe (420-800 nm) by focusing the 800 nm fundamental onto a Sapphire crystal. Electrochemical impedance spectroscopy was obtained at a 0 V reverse direct current (DC) bias and 100 mV alternating current (AC) amplitude applied at a frequency range of 1 Hertz (Hz)-1 megahertz (MHz) using a Gamry Interface 1000E potentiostat. The charge-carrier mobility (μ) was determined using Mott-Gurney (M-G) analysis in trap-controlled space-charge limited current (SCLC) region of the J-V curves. The SCLC region shows a quadratic response, μ=(8JL³)/(9εε₀V²), where ε₀ is the dielectric constant of vacuum, ε is the dielectric constant of TPPcarzSbBr₄ obtained by the via capacitance measurements, and μ is the carrier mobility (see also, Worku et al., Band Edge Control of Quasi-2D Metal Halide Perovskites for Blue Light-Emitting Diodes with Enhanced Performance, Advanced Functional Materials, 31 (45), 2103299, 2021; which is hereby incorporated by reference herein in its entirety).

### Example 1—Synthesis of OMHH

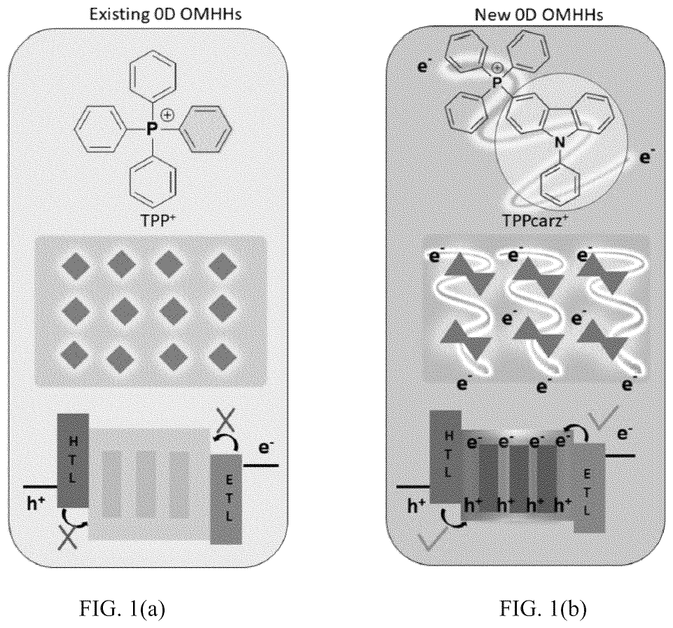

In order to turn TPP+ into a semiconducting organic cation, one phenyl ring in TPP+ was replaced with phenylcarbazole, a charge transporting unit to give TPPcarz+, as shown in FIG. 1(b) (compared to TPP+ as shown in FIG. 1(a)). The rationally designed triphenyl(9-phenyl-9H-carbazol-3-yl) phosphonium cation (TPPcarz+) was then used for the preparation of 0D OMHHs. The charge injection and transport in 0D OMHHs containing TPPcarz+were tested and compared with those including TPP+. Both cations were used as emitting layers in electrically driven LEDs (see also FIGS. 1(a) and 1(b)).

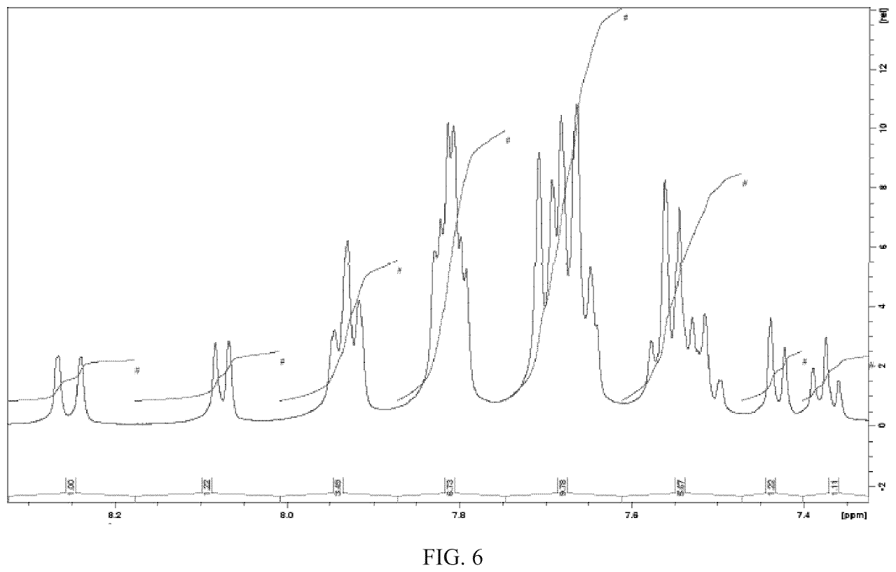

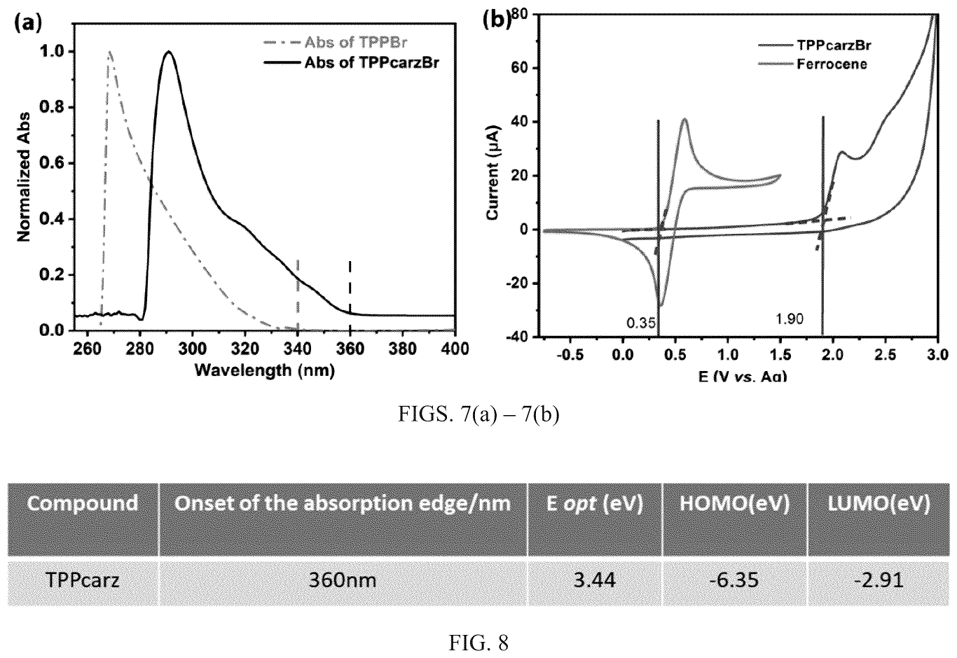

TPPcarzBr was first synthesized according to the scheme shown in FIG. 2(a) (see also Xu et al., supra.) and characterized by ¹H NMR, as shown in FIG. 6. The photophysical properties of TPPcarzBr were also characterized, with results shown in FIGS. 7(a), 7(b), and 8. It was found that TPPcarzBr has an optical gap of 3.44 electron Volts (eV), lower than that of TPPBr (3.64 eV). These energetics suggested that TPPcarz+ could perform better than TPP+ as a semiconducting host for light emitting metal halides with green and red emissions, as the energetic gap is large enough to achieve site isolation for metal halides, while ensuring efficient charge injection, transport, and recombination, as shown in FIG. 1(b).

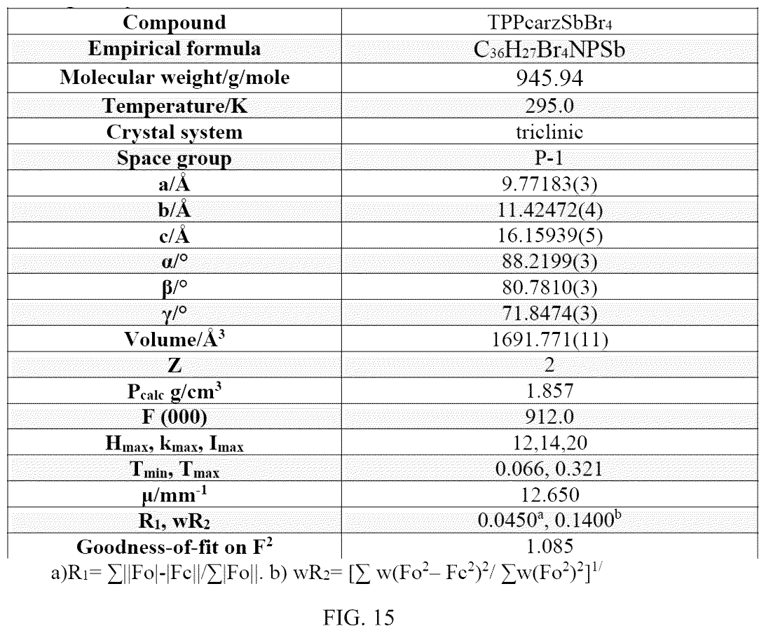

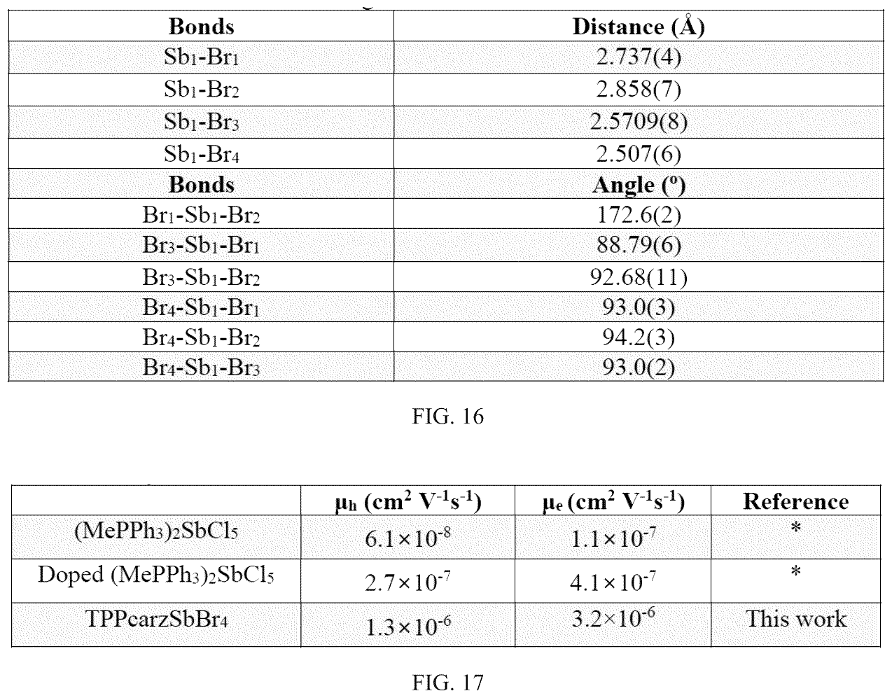

TPPcarzSbBr4 single crystals were prepared by diffusing an antisolvent (diethyl ether in this example, though any suitable antisolvent could be used) into a dichloromethane precursor solution of antimony tribromide (SbBr₃) and TPPcarzBr in a 1:2 molar ratio at room temperature (see FIG. 2(b)). The single crystals were transparent and yellow under ambient light (see FIG. 2(c)), but exhibited vibrant red emission under ultraviolet (UV) excitation at a wavelength of 365 nanometers (nm) (see FIG. 2(d)). The crystal structure of TPPcarzSbBr₄ was determined using single crystal X-ray diffraction (see the tables in FIGS. 15 and 16), and adopted a triclinic space group P1⁻ structure with edges shared metal halide dimers Sb₂Br₈²⁻ co-crystallizing with TPPcarz+ (see also FIG. 2(c)).

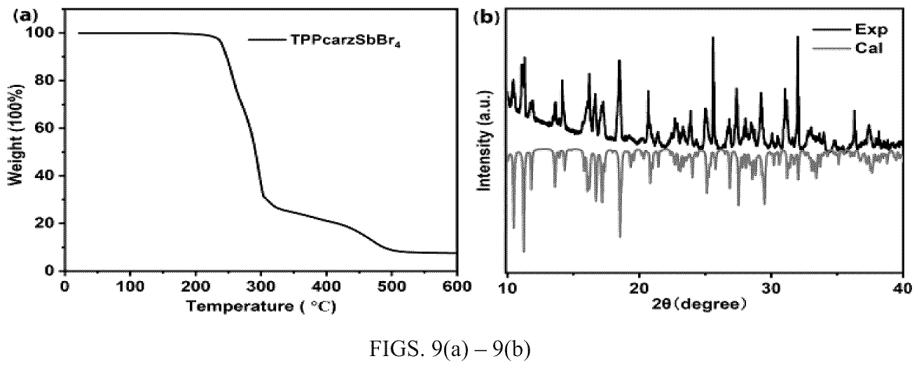

The thermal stability of TPPcarzSbBr₄ was characterized using thermal gravimetric analysis (TGA), which showed little to no decomposition up to 220° C. (see FIG. 9(a)). The high phase purity of prepared TPPcarzSbBr₄ single crystals was confirmed by the powder X-ray diffraction (PXRD) patterns (see FIG. 9(b)).

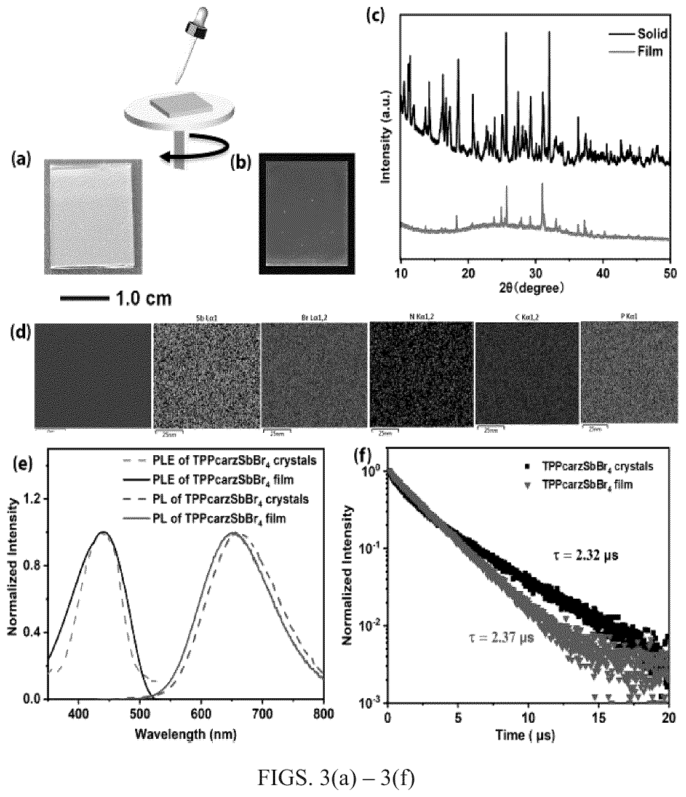

For electrically driven LEDs, emitting layers in the form of smooth thin films were tested. In order to make TPPcarzSbBr₄ thin films, a TPPcarzSbBr₄ precursor solution containing 1:2 molar ratio of SbBr₃:TPPcarzBr was spin casted. The same solution used for the preparation of single crystals was used here. The fabricated thin films showed almost identical optical properties as those of single crystals under ambient and UV (365 nm) lights (see FIG. 3(a) for ambient and FIG. 3(b) for UV light), which suggested the formation of TPPcarzSbBr₄. This was confirmed by PXRD results with similar patterns recorded for TPPcarzSbBr₄ single crystals and solution processed thin films, as shown in FIG. 3(c). The chemical compositions of prepared thin films were further determined by an elemental mapping (see FIG. 3(d)), which showed the presence of Sb, Br, carbon (C), nitrogen (N), and phosphorous (P) with a uniform spatial distribution.

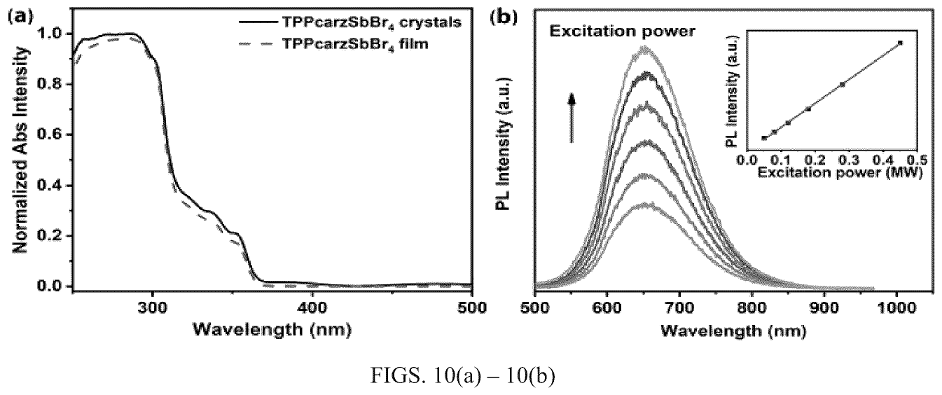

The photophysical properties of both TPPcarzSbBr₄ single crystals and solution processed thin films were characterized with absorption spectroscopy (see FIG. 10(a)), as well as photoluminescence (PL) and excitation (PLE) spectroscopies (see FIG. 3(c)), which exhibited almost identical features. The absorption below 370 nm was mainly attributed to TPPcarz+, while the red emission peaked at 653 nm with a full width at half-maximum (FWHM) of 141 nm, which was believed to be from Sb₂Br₈²⁻.

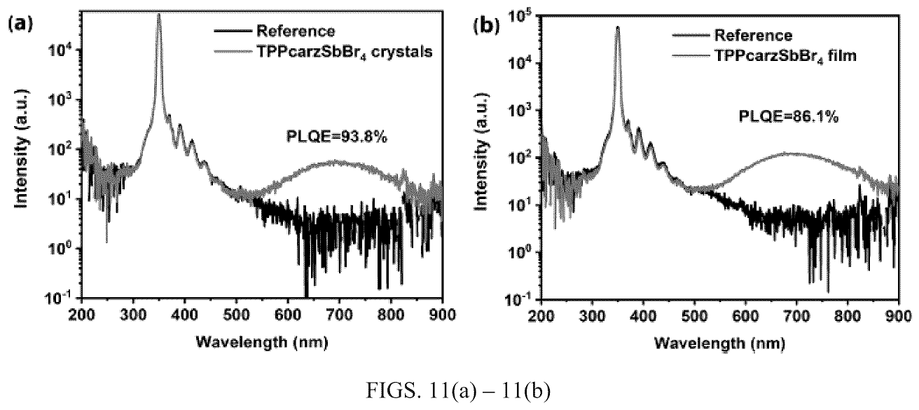

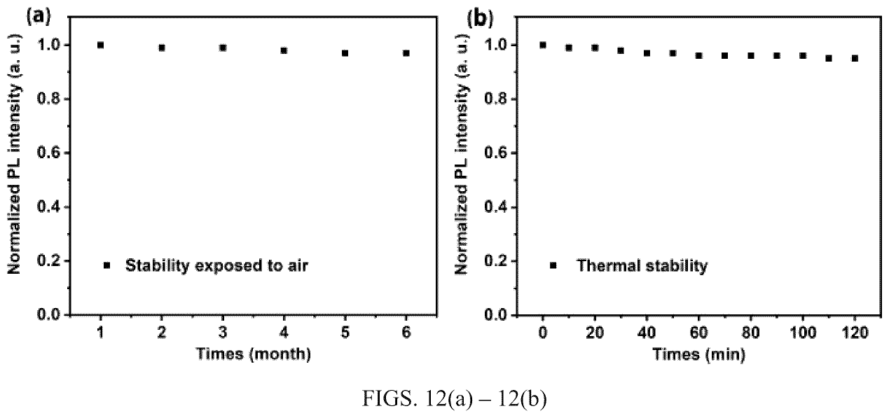

An excited-state lifetime of 2.3 microseconds (μs) upon excitation at 365 nm was recorded, which suggested the phosphorescence nature of the emission. Such a broadband emission with a large Stokes shift and a long lifetime has been observed in Sb-based 0D OMHHs (see also He et al., Highly Stable Organic Antimony Halide Crystals for X-ray Scintillation, ACS Materials Letters 20, 2 (6), 633-638, 2020; which is hereby incorporated by reference herein in its entirety). Excitation power-dependent PL spectra (FIG. 10(b)) confirmed that the emission of TPPcarzSbBr₄ was from the localized exciton recombination in metal halide spcies (see also Chen et al., Excitation-Dependent Emission Color Tuning of 0D Cs2InBr5·H2O at High Pressure, Advanced Functional Materials, 31 (38), 2104923, 2021; which is hereby incorporated by reference herein in its entirety). The PLQEs of TPPcarzSbBr₄ single crystals and thin films were measured to be 93.8% and 86.1%, respectively (see FIGS. 11(a) and 11(b)), which were sufficiently high values for the light emitting layers to be used for electrically driven LEDs. Moreover, solution processed TPPcarzSbBr₄ thin films were found to exhibit high thermal and atmosphere stability, as they maintained the same photoluminescence after 2 hours on the top of a 150° C. hot plate and 6 months' storage in air (see FIGS. 12(a) and 12(b)).

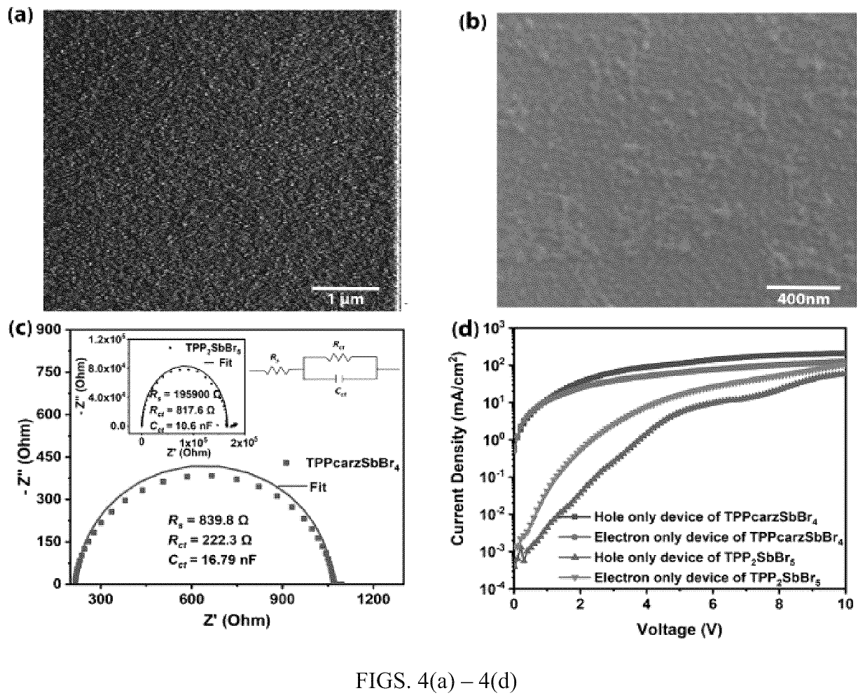

The surface morphology of solution processed TPPcarzSbBr₄ thin films was characterized by atomic force microscopy (AFM) and scanning electron microscopy (SEM), as shown in FIGS. 4(a) and 4(b), respectively. The root mean square roughness of TPPcarzSbBr₄ thin films was determined to be around 0.038 nm, which was a sufficiently low value needed for device integration (see also Xu et al., supra.).

SEM images also confirmed the formation of smooth thin films with uniformly distributed crystalline phases without any deep grain boundaries. The high quality of solution processed thin films was mainly attributed to the relatively high viscosity of TPPcarzBr, which likely played a key role in the crystallization process during the film formation (see also; Riera-Galindo et al., Role of Polymorphism and Thin-Film Morphology in Organic Semiconductors Processed by Solution Shearing, ACS Omega, 3 (2), 2329-2339, 2018; and Kundu et al., High-Tg Carbazole Derivatives as Blue-Emitting Hole-Transporting Materials for Electroluminescent Devices, Advanced Functional Materials, 13 (6), 445-452, 2003; both of which are hereby incorporated by reference herein in their entireties). With high PLQE and excellent film morphology achieved in solution processed TPPcarzSbBr₄ thin films, suitable electronic properties were the last major requirement for them to act as emitting layer in electrically driven LEDs.

In order to support the design of conductive thin films based on 0D OMHHs, electrochemical impedance spectroscopy (EIS) was performed to probe the conductivity of solution processed TPPcarzSbBr₄ thin films. The Nyquist plots of devices with a structure of ITO/PEDOT:PSS (40 nm)/PVK (35 nm)/TPPcarzSbBr₄ (40 nm)/Ca (20 nm)/Al (100 nm) measured at a reverse bias voltage of 0 V are shown in FIG. 4(c).

The charge transport resistance (R_{ct}), the series resistance (Rₛ), and the chemical capacitance (C_{ct}) were obtained by fitting electrochemical impedance spectroscopy (EIS) data according to the relevant equivalent circuit. Also tested was the conducting performance of a device based on TPP₂SbBr₅ for comparison (inset of FIG. 4(c)), a 0D OMHH containing TPP+ cations and SbBr₅²⁻ anions (see also, Morad et al., Hybrid 0D Antimony Halides as Air-Stable Luminophores for High-Spatial-Resolution Remote Thermography. Advanced Materials, 33 (9), 2007355, 2021; which is hereby incorporated by reference herein in its entirety). It was found that TPPcarzSbBr₄ thin films had much smaller R_{ct}=222.3 Ohms (Ω) and Rₛ=839.8 Ω than those of TPP₂SbBr₅ thin films (R_{ct}=817.6 Ω and Rₛ=195,900 Ω), which suggested significantly improved charge transport upon the incorporation of phenylcarbazole units into TPP+.

### Example 2—Preparation and Testing of Electronic Devices

Single-carrier devices were fabricated in order to further verify the improved charge transport capabilities of TPPcarzSbBr₄ thin films over TPP₂SbBr₅ thin films.

The device characteristics for the electron-only devices (ITO/tin oxide (SnO₂) (30 nm)/TPPcarzSbBr₄ (40 nm)/LiF (2 nm)/Al (100 nm)) and the hole-only devices (ITO/PEDOT:PSS (40 nm)/TPPcarzSbBr₄ (40 nm)/MoOx (10 nm)/Al (100 nm)) are shown in FIG. 4(d).

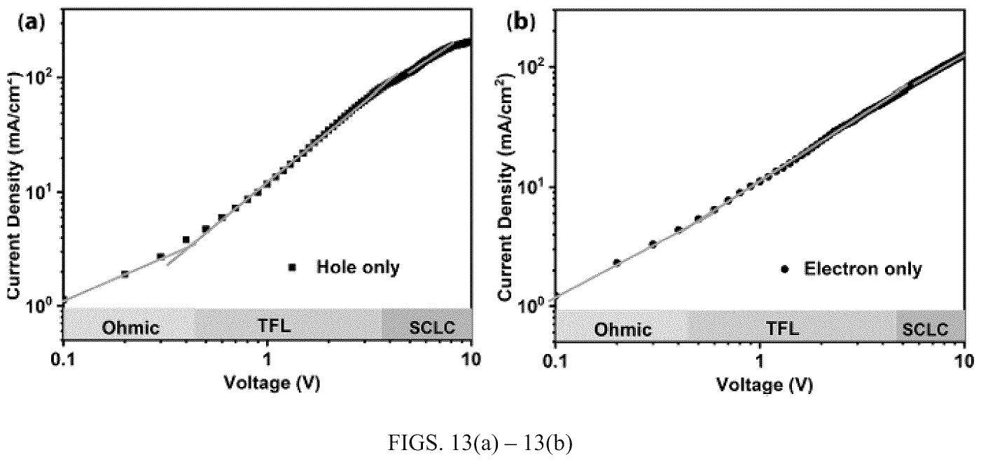

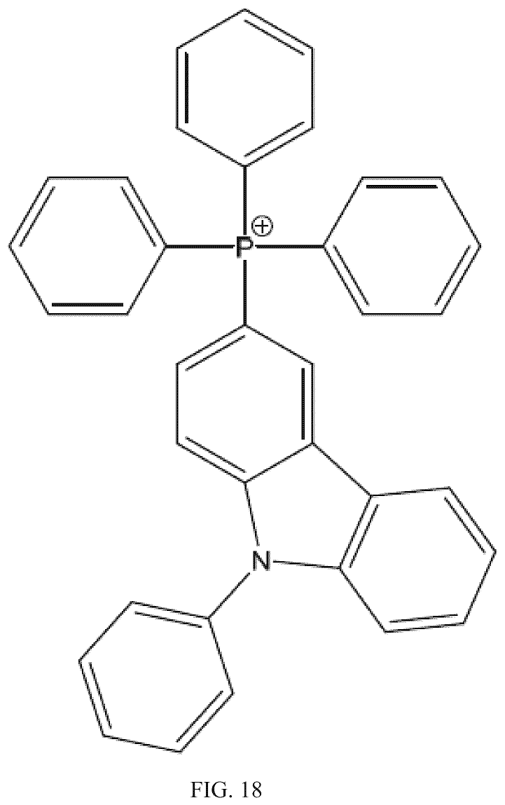

As compared to devices based on TPP₂SbBr₅ thin films, devices based on TPPcarzSbBr₄ thin films exhibited much higher current density with more balanced charge injection. The hole and electron charge carrier mobilities of TPPcarzSbBr₄ thin films were determined to be 1.3×10⁻⁶ square centimeters per Volt per second (cm²/V-s) and 3.2×10⁻⁶ cm²/V-s, respectively (see FIGS. 13(a) and 13(b)), which are much higher than those of related art 0D OMHHs (see the table in FIG. 17).

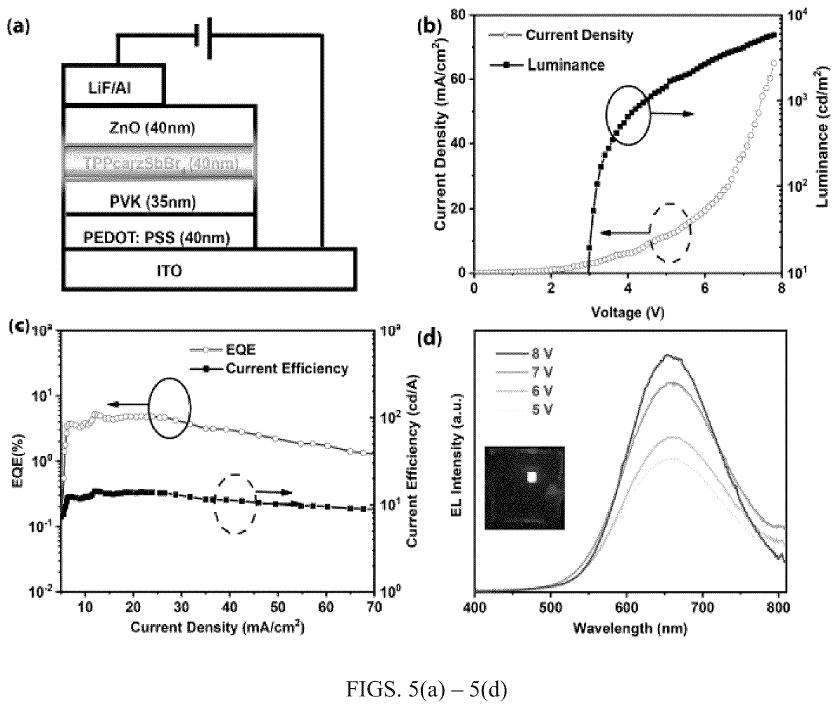

In this example, electrically driven LEDs were fabricated using the device structure as shown in FIG. 5(a) (ITO/PEDOT:PSS (40 nm)/PVK (35 nm)/TPPcarzSbBr₄ (40 nm)/zinc oxide (ZnO) (40 nm)/LiF (2 nm)/Al (100 nm). The device turn-on voltage was 3.1 V, which suggested efficient charge injection from the hole transporting layer (HTL) and electron transporting layer (ETL) into the emitting layer.

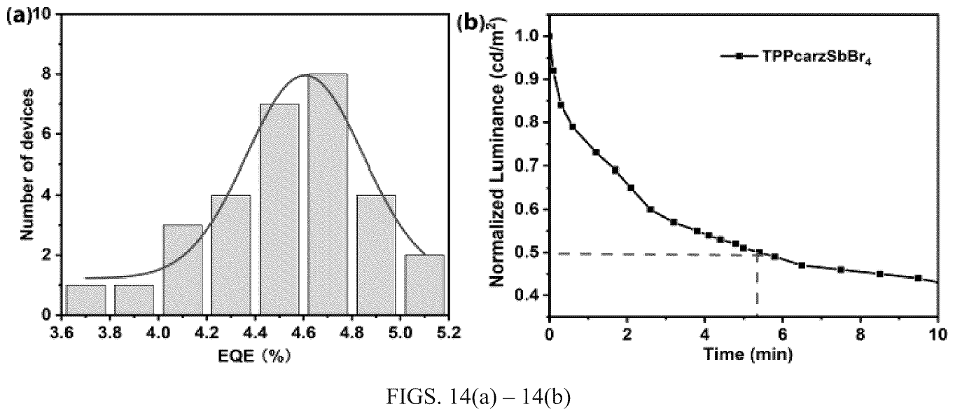

An external quantum efficiency (EQE) of 5.12%, a luminance of 5957 cd/m², and a current efficiency of 14.2 cd/A (see FIGS. 5(b) and 5(c)) were achieved, which are believed to be the best values for red LEDs based on 0D OMHHs. The reproducibility of TPPcarzSbBr₄ based LEDs was assessed with results shown in FIG. 14(a), where a small relative deviation was observed.

The spectral stability was evaluated by varying bias from 5V to 8 V (see FIG. 5(d)), where the red electroluminescence (EL) centered at 653 nm shows little to no shift. The half lifetime (T₅₀) at an initial luminance of 100 cd/m² for an un-encapsulated device was measured to be around 5.2 minutes (see FIG. 14(b)), which was better than those of related art LEDs based on 0D OMHHs (see also Kundu et al., supra.). The examples herein demonstrated that introducing semiconducting units to organic cations improved the performance of 0D OMHHs in electronic devices.

It should be understood that the examples and embodiments described herein are for illustrative purposes only and that various modifications or changes in light thereof will be suggested to persons skilled in the art and are to be included within the spirit and purview of this application.

All patents, patent applications, provisional applications, and publications referred to or cited herein are incorporated by reference in their entirety, including all figures and tables, to the extent they are not inconsistent with the explicit teachings of this specification.

What is claimed is:

1. An organic metal halide hybrid (OMHH) having the following formula:
(Cat)aM^{+b}Xy,
where Cat is a phosphonium cation comprising a phosphorus atom substituted with three aryl C1-C20 hydrocarbyl substituents and one heteroaryl C1-C20 hydrocarbyl substituent,
where M is a metal,
where b is the oxidation state of the metal, and
where X is a halogen.

2. The OMHH according to claim 1, wherein a+b=y.

3. The OMHH according to claim 1, wherein the heteroaryl C1-C20 hydrocarbyl substituent comprises a carbazole moiety.

4. The OMHH according to claim 3, wherein the carbazole moiety is a phenyl-carbazole moiety.

5. The OMHH according to claim 1, wherein the three aryl C1-C20 hydrocarbyl substituents are phenyl.

6. The OMHH according to claim 1, wherein the phosphonium cation is triphenyl(9-phenyl-9H-carbazol-3-yl) phosphonium with the following structure:

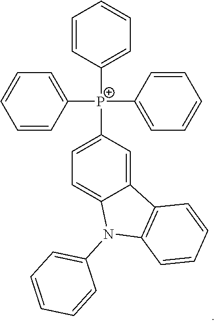 [SMILES: c1ccc(-n2c3ccccc3c3cc([P+](c4ccccc4)(c4ccccc4)c4ccccc4)ccc32)cc1]

7. The OMHH according to claim 1, wherein M is not lead (Pb).

8. The OMHH according to claim 1, wherein M is antimony (Sb).

9. The OMHH according to claim 1, wherein X is bromine (Br).

10. The OMHH according to claim 1, wherein the OMHH has a zero-dimensional (0D) crystal structure.

11. The OMHH according to claim 1, wherein the OMHH has a crystal structure comprising light emitting antimony bromide dimer anions (Sb₂Br₈²⁻) surrounded and isolated by the phosphonium cation.

12. The OMHH according to claim 1, wherein the OMHH is in the form of discrete crystals, wherein the discrete crystals have a photoluminescent quantum efficiency (PLQE) of at least 90%.

13. The OMHH according to claim 1, wherein the OMHH is in the form of a thin film, wherein the thin film has a PLQE of at least 85%.

14. The OMHH according to claim 1, wherein the OMHH has a structure of the following formula:
(triphenyl(9-phenyl-9H-carbazol-3-yl) phosphonium)+SbBr₄.

15. An electrically driven light emitting diode, comprising:
a first electrode;
a light emitting layer comprising the OMHH according to claim 1; and
a counter electrode;
wherein the light emitting layer is disposed between the first electrode and the counter electrode.

16. The device according to claim 15, further comprising at least one of:
a hole transporting layer disposed between the first electrode and the light emitting layer; and
an electron transporting layer disposed between the counter electrode and the light emitting layer.

17. The device according to claim 15, wherein the device is a hole-only device.

18. The device of according to claim 15, wherein the device is an electron-only device.

19. An organic metal halide hybrid (OMHH) having the following formula:
(Cat)aM^{+b}Xy,
where Cat is a phosphonium cation comprising a phosphorus atom substituted with three aryl C1-C20 hydrocarbyl substituents and one heteroaryl C1-C20 hydrocarbyl substituent,
where M is a metal,
where b is the oxidation state of the metal,
where X is a halogen,
wherein a+b=y,
wherein the heteroaryl C1-C20 hydrocarbyl substituent comprises a phenyl-carbazole moiety,
wherein the three aryl C1-C20 hydrocarbyl substituents are phenyl,
wherein M is antimony (Sb),
wherein X is bromine (Br),
wherein the OMHH has a zero-dimensional (0D) crystal structure,
wherein: the OMHH is in the form of discrete crystals and the discrete crystals have a photoluminescent quantum efficiency (PLQE) of at least 90%; or the OMHH is in the form of a thin film and the thin film has a PLQE of at least 85%, and
wherein the phosphonium cation is triphenyl(9-phenyl-9H-carbazol-3-yl) phosphonium with the following structure:

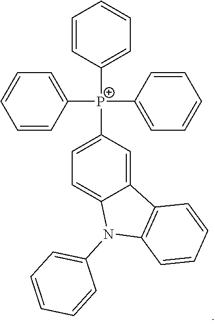 [SMILES: c1ccc(-n2c3ccccc3c3cc([P+](c4ccccc4)(c4ccccc4)c4ccccc4)ccc32)cc1]

20. An electrically driven light emitting diode, comprising:
a first electrode;
a counter electrode;
a light emitting layer comprising the OMHH according to claim 19, the light emitting layer being disposed between the first electrode and the counter electrode;
a hole transporting layer disposed between the first electrode and the light emitting layer, and
an electron transporting layer disposed between the counter electrode and the light emitting layer.
